(19) United States
(12) Patent Application Publication
(10) Pub. No.: US 2025/0118708 A1
(43) Pub. Date: Apr. 10, 2025

(54) FRONT-END CIRCUIT AND SEMI-CONDUCTOR DEVICE

(71) Applicant: RichWave Technology Corp., Taipei (TW)

(72) Inventor: Kuang-Lieh Wan, Taipei (TW)

(73) Assignee: RichWave Technology Corp., Taipei (TW)

(21) Appl. No.: 18/533,175

(22) Filed: Dec. 8, 2023

(30) Foreign Application Priority Data
Oct. 4, 2023 (TW) 112138067

(51) Int. Cl. H01L 25/065; H01L 23/00; H01L 23/66; H03H 7/38

(52) U.S. Cl. CPC H01L 25/0655; H01L 23/66; H01L 24/48; H03H 7/38; H01L 2223/6655; H01L 2224/48137

(57) ABSTRACT

A front-end circuit and a semi-conductor device are provided. The front-end circuit includes an amplifying circuit, a switching circuit, a coupler and at least one bonding wire. The amplifying circuit has a first end for receiving a radio-frequency signal to be amplified. The switching circuit has a first end coupled to a second end of the amplifying circuit. The coupler has a first coupling element and a second coupling element arranged adjacently. A first end of the first coupling element is coupled to a second end of the switching circuit. A second end of the first coupling element is coupled to a signal transmission end. The bonding wire has a first end coupled to the first end of the first coupling element, and a second end of the bonding wire is coupled to the second end of the first coupling element.

### CROSS-REFERENCE TO RELATED APPLICATION

This application claims the priority benefit of Taiwan application serial no. 112138067, filed on Oct. 4, 2023. The entirety of the above-mentioned patent application is hereby incorporated by reference herein and made a part of this specification.

### BACKGROUND

### Technical Field

The disclosure relates to a front-end circuit and a semi-conductor device, and particularly relates to a front-end circuit and a semi-conductor device that can reduce the insertion power loss of an amplifying circuit.

### Description of Related Art

In a device for transmitting and receiving radio-frequency signals, the amplifying circuit is often used to couple to a coupler to amplify and process the radio-frequency signals, and then output to a radio frequency circuit or a signal transmission end for transmitting and receiving operations. In the conventional architecture, the coupler often causes coupler loss, which reduces the power of the transmitted and received signals, thereby adversely affecting the quality of the signals. Therefore, how to reduce the insertion power loss of the amplifying circuit is an important issue for engineers in this field.

### SUMMARY

The disclosure provides a front-end circuit and a semi-conductor device that can reduce the insertion power loss of the amplifying circuit.

The front-end circuit of the disclosure includes an amplifying circuit, a switching circuit, a coupler, and at least one bonding wire. The amplifying circuit has a first end for receiving a radio-frequency signal to be amplified. The switching circuit has a first end coupled to a second end of the amplifying circuit. The coupler has a first coupling element and a second coupling element arranged adjacently. A first end of the first coupling element is coupled to a second end of the switching circuit. A second end of the first coupling element is coupled to a signal transmission end. The bonding wire has a first end coupled to the first end of the first coupling element, and a second end of the bonding wire is coupled to the second end of the first coupling element.

The semi-conductor device of the disclosure includes a first chip, a second chip, a third chip, and at least one bonding wire. The first chip is configured to dispose an amplifying circuit. A first end of the amplifying circuit receives a radio-frequency signal to be amplified. The second chip is configured to dispose a switching circuit. The switching circuit has a first end coupled to a second end of the amplifying circuit. The third chip is configured to dispose a coupler. The coupler has a first coupling element and a second coupling element arranged adjacently. A first end of the first coupling element is coupled to a second end of the switching circuit, and a second end of the first coupling element is coupled to a signal transmission end. The bonding wire has a first end coupled to the first end of the first coupling element, and a second end of the bonding wire is coupled to the second end of the first coupling element.

Based on the above, in the front-end circuit according to the disclosure, the switching circuit is disposed between the amplifying circuit and the coupler, and the at least one bonding wire is disposed on the first coupling element of the coupler. Through disposing the bonding wire, the insertion power loss of the amplifying circuit can be reduced. In addition, under the configuration of the front-end circuit according to the disclosure, the power of a coupling signal outputting by the coupler can be correctly sensed, and the mismatch phenomenon between the amplifying circuit and the switching circuit can be reduced.

### BRIEF DESCRIPTION OF THE DRAWINGS

FIG. 1 is a schematic diagram of a front-end circuit according to an embodiment of the disclosure.

FIG. 2A to FIG. 2D are respectively schematic diagrams of multiple embodiments of a bonding wire on a first coupling element in the front-end circuit according to embodiments of the disclosure.

FIG. 3 is a schematic diagram of an amplifying circuit in the front-end circuit according to an embodiment of the disclosure.

FIG. 4 is a schematic diagram of a semi-conductor device according to an embodiment of the disclosure.

### DESCRIPTION OF THE EMBODIMENTS

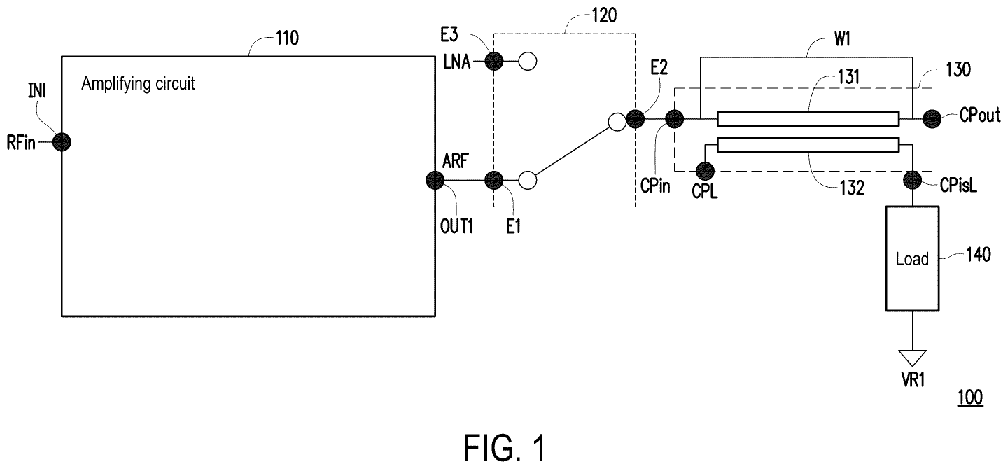

Please refer to FIG. 1. FIG. 1 is a schematic diagram of a front-end circuit according to an embodiment of the disclosure. A front-end circuit 100 may be a front-end circuit of a wireless signal transceiver. The front-end circuit 100 includes an amplifying circuit 110, a switching circuit 120, a coupler 130, and a bonding wire W1. The amplifying circuit 110 has a first end IN1 and a second end OUT1. The first end IN1 of the amplifying circuit 110 may be the input end, and the second end OUT1 of the amplifying circuit 110 may be the output end. The first end IN1 of the amplifying circuit 110 is configured to receive a radio-frequency signal to be amplified RFin. The second end OUT1 of the amplifying circuit 110 is configured to transmit an amplified radio-frequency signal ARF.

The switching circuit 120 has a first end E1, a second end E2, and a third end E3. The first end E1 of the switching circuit 120 is coupled to the second end OUT1 of the amplifying circuit 110. The second end E2 of the switching circuit 120 is coupled to the coupler 130. The third end E3 of the switching circuit 120 may be coupled to a low noise amplifier LNA. The switching circuit 120 is configured to perform a switching operation, so that the second end E2 may be coupled to the first end E1 or may be coupled to the third end E3. In detail, when the wireless signal transceiver is in the signal transmitting mode, the first end E1 of the switching circuit 120 may be coupled to the second end E2. On the other hand, when the wireless signal transceiver is in the signal receiving mode, the third end E3 of the switching circuit 120 may be coupled to the second end E2.

The coupler 130 includes a first coupling element 131 and a second coupling element 132. The coupler 130 has an input end CPin, an output end CPout, a coupling end CPL, and an isolating end CPisL. The first end of the first coupling element 131 is coupled to the input end CPin of the coupler 130, and the second end of the first coupling element 131 is coupled to the output end CPout of the coupler 130, and may be coupled to a signal transmission end. The signal transmission end is, for example, an antenna end. The first end of the second coupling element 132 is coupled to the coupling end CPL of the coupler 130, and the second end of the second coupling element 132 is coupled to the isolating end CPisL of the coupler 130. In addition, a load 140 is coupled between the isolating end CPisL of the coupler 130 and a reference voltage end VR1, and the coupling end CPL can output coupling signals to perform power detection.

In this embodiment, the first end of a bonding wire W1 is coupled to the first end of the first coupling element 131, and the second end of the bonding wire W1 is coupled to the second end of the first coupling element 131. That is to say, the bonding wire W1 and the first coupling element 131 may be disposed in a manner of being connected in parallel. When performing the transmitting operation of the radio-frequency signal, the bonding wire W1 may serve as a transmitting medium for part of the energy of the radio-frequency signal, thereby reducing the insertion power loss generated by the amplifying circuit 110 due to the switching circuit 120. Therefore, the power of the coupling signal output by the coupler 130 can be correctly sensed, and the mismatch phenomenon between the amplifying circuit 110 and the switching circuit 120 can be reduced, and the overall performance of the system can be effectively improved. In this embodiment, the length of the first coupling element 131 may be substantially equal to the length of the bonding wire W1. In practice, the length of the first coupling element 131 may have a certain amount of error from the length of the bonding wire W1, for example, within ±10%. It is worth mentioning that, in order to prevent the bonding wire W1 from affecting the transmitting operation of the radio-frequency signal on the first coupling element 131, a signal coupling amount between the first coupling element 131 and the bonding wire W1 may be less than a preset threshold value.

The coupling amount may be adjusted through adjusting the distance between the bonding wire W1 and the first coupling element 131. The bonding wire W1 may be a wire formed in an arc-shape and cross connect between the first end and the second end of the first coupling element 131. Here, by increasing the arc height of the bonding wire W1, the signal coupling amount between the first coupling element 131 and the bonding wire W1 can be reduced. The threshold value may be set by a designer according to the actual application status of the front-end circuit 100, and the disclosure is not limited thereto.

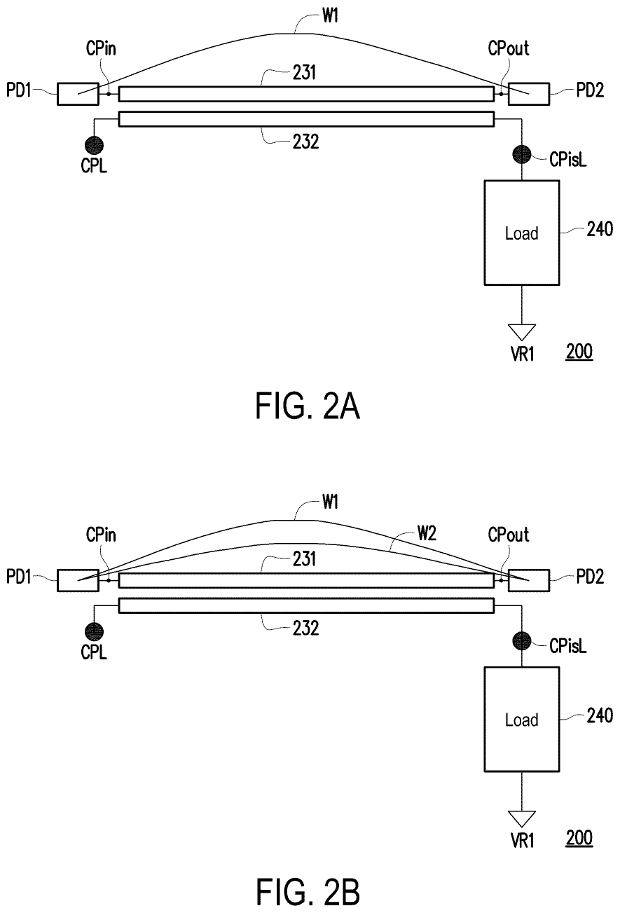

In the following description, please refer to FIG. 2A to FIG. 2D. FIG. 2A to FIG. 2D are respectively schematic diagrams of multiple embodiments of the bonding wire on the first coupling element in the front-end circuit according to embodiments of the disclosure. In FIG. 2A, a coupler 200 includes a first coupling element 231 and a second coupling element 232. The first end of the first coupling element 231 coupled to the input end CPin of the coupler 200 is also coupled to a bonding pad PD1. The second end of the first coupling element 231 coupled to the output end CPout of the coupler 200 is also coupled to a bonding pad PD2. The bonding wire W1 is disposed between the bonding pads PD1 and PD2, in which an end of the bonding wire W1 is coupled to bonding pad PD1, another end of the bonding wire W1 is coupled to the bonding pad PD2, and a state of being connected in parallel with the first coupling element 231 is formed. In this embodiment, the bonding wire W1 may be a wire formed in an arc-shape cross connecting above the first coupling element 231. Furthermore, by controlling the arc height of the bonding wire W1, the signal coupling amount between the bonding wire W1 and the first coupling element 231 can be controlled.

On the other hand, in this embodiment, the second coupling element 232 is coupled between the isolating end CPisL and the coupling end CPL of the coupling 200. The isolating end CPisL is coupled to an end of a load 240, and another end of the load 240 is coupled to the reference voltage end VR1, in which the reference voltage end VR1 is configured to receive the reference voltage. The reference voltage end VR1 may be a ground end.

In FIG. 2B, multiple bonding wires W1 and W2 are disposed between the bonding pads PD1 and PD2. The bonding wires W1 and W2 are connected in parallel with the first coupling element 231. Similarly, by controlling the arc heights of the bonding wires W1 and W2, the signal coupling amount between the bonding wires W1 and W2 and the first coupling element 231 can be controlled.

It is worth mentioning that, in other embodiments of the disclosure, the quantity of the bonding wires disposed on the bonding pads PD1 and PD2 may also be greater than 2. Engineers may adjust the quantity of the bonding wires according to actual conditions, and the disclosure is not limited thereto. The embodiments shown in FIG. 2A and FIG. 2B are merely examples for illustration and are not intended to limit the scope of the disclosure.

In FIG. 2C, a relay bonding pad IPD1 may be disposed around the coupler 200. Also, the bonding wire W1 may be split into sub-bonding wires SW1 and SW2. An end of the sub-bonding wire SW1 is coupled to the bonding pad PD1, and another end of the sub-bonding wire SW1 is coupled to the relay bonding pad IPD1; an end of the sub-bonding wire SW2 is coupled to the relay bonding pad IPD1, and another end of the sub-bonding wire SW2 is coupled to the bonding pad PD2. In this embodiment, the distance between the bonding wire W1 and the first coupling element 231 can be adjusted through the position of the disposed relay bonding pad IPD1, and the signal coupling amount between the bonding wire W1 and the first coupling element 231 can be further adjusted. In addition, through the bonding wire W1 being split into the sub-bonding wires SW1 and SW2, and forming the sub-bonding wires SW1 and SW2 between the fixedly disposed bonding pad PD1, the relay bonding pad IPD1, and the bonding pad PD2, the bonding wire W1 can have a stable shape, which can reduce the possibility that the excessively long bonding wire W1 causes shaking due to the processing or use of the coupler 200 and affect the signal coupling amount between the bonding wire W1 and the first coupling element 231. Therefore, the stability of the performance of the coupler 200 can be effectively maintained.

In FIG. 2D, multiple relay bonding pads IPD1 to IPDN may be disposed around the coupler 200. Correspondingly, the bonding wire W1 may be split into N+1 sub-bonding wires SW1 to SWN+1. The sub-bonding wires SW1 to SWN+1 are respectively coupled between the bonding pad PD1 and the bonding pad PD2 by sequentially being disposed alternately and connected in series with the multiple relay bonding pads IPD1 to IPDN.

It is worth mentioning that, in this embodiment, the quantity of the relay bonding pads IPD1 to IPDN may be greater than one and may be decided by the designer, and the disclosure is not limited thereto. In FIG. 2C, the length of the first coupling element 231 may be substantially equal to the total length of the sub-bonding wires SW1 and SW2. In FIG. 2D, the length of the first coupling element 231 may be substantially equal to the total length of the sub-bonding wires SW1 to SWN+1. Specifically, the length of the first coupling element 131 may have a certain amount of error from the total length of the sub-bonding wires SW1 and SW2, for example, within ±10%; and the length of the first coupling element 131 may have a certain amount of error from the total length of the sub-bonding wires SW1 to SWN+1, for example, within ±10%.

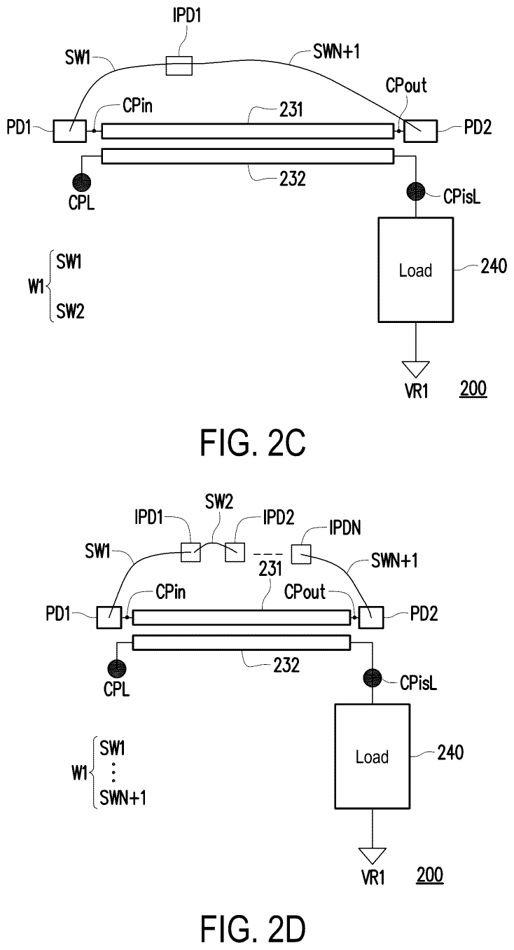

Please refer to FIG. 3. FIG. 3 is a schematic diagram of an amplifying circuit in the front-end circuit according to an embodiment of the disclosure. An amplifying circuit 300 includes a power amplifier PA and an inductance L1. The input end of the power amplifier PA is coupled to the input end IN1 of the amplifying circuit 300. The input end of the power amplifier PA is for receiving the radio-frequency signal to be amplified RFin. An output end OUTA of the power amplifier PA is coupled to the inductance L1, and the output end OUTA of the power amplifier PA is for transmitting the amplified radio-frequency signal ARF to the inductance L1. Another end of the inductance L1 is coupled to an endpoint E31, and then coupled to an output end OUT1 of the amplifying circuit 300 through a capacitance C1. In addition, in this embodiment, the amplifying circuit 300 also includes a capacitance C2. The capacitance C2 may be coupled between the endpoint E31 and a reference ground end VR2.

In this embodiment, the capacitance C1 may provide the DC isolation effect; the inductance L1 and the capacitance C2 may be configured to form a matching circuit coupled to the output end OUTA of the power amplifier PA. The matching circuit may also be replaced by capacitance or inductance networks of other coupling forms. The order of the inductance L1 and the capacitances C1 and C2 may also be adjusted according to requirements, and the disclosure is not limited thereto. In addition, the circuit structure of the power amplifier PA may be implemented by using any power amplifying circuit well-known to persons skilled in the art, and the disclosure is not limited thereto.

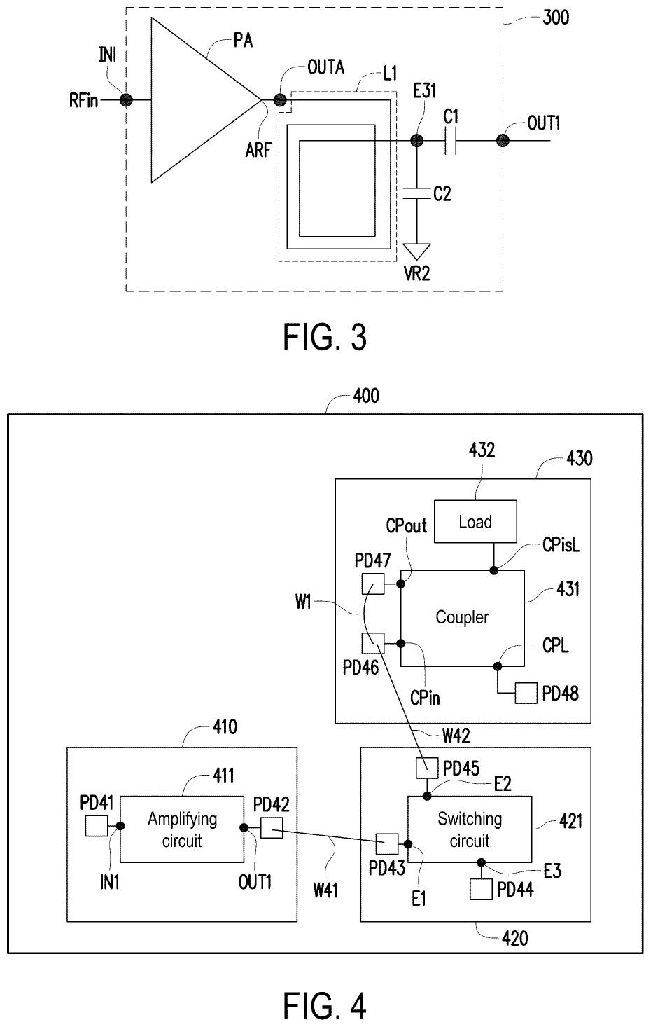

Please refer to FIG. 4. FIG. 4 is a schematic diagram of a semi-conductor device according to an embodiment of the disclosure. A semi-conductor device 400 includes a first chip 410, a second chip 420, and a third chip 430. The first chip 410 has an amplifying circuit 411 and bonding pads PD41 and PD42. The first end IN1 of the amplifying circuit 411 is coupled to the bonding pad PD41, and the second end OUT1 of the amplifying circuit 411 is coupled to the bonding pad PD42. The first end IN1 of the amplifying circuit 411 may be the input end, and the second end OUT1 of amplifying circuit 411 may be the output end. For circuit details of the amplifying circuit 411, reference may be made to the embodiment in FIG. 3, and will not be described in detail here.

The second chip 420 has a switching circuit 421 and bonding pads PD43, PD44, and PD45. The first end E1 of the switching circuit 421 is coupled to the bonding pad PD43, the second end E2 of the switching circuit 421 is coupled to the bonding pad PD45, and the third end E3 of the switching circuit 421 is coupled to the bonding pad PD44. The switching circuit 421 may allow the second end E2 to be coupled to the first end E1 or the third end E3 through the switching operation. For circuit details of the switching circuit 421, reference may be made to the embodiment in FIG. 1, and will not be described in detail here.

In addition, the third chip 430 has a coupler 431, bonding pads PD46 to PD48, and a load 432. The input end CPin of the coupler 431 is coupled to the bonding pad PD46; the output end CPout of the coupler 431 is coupled to the bonding pad PD47; the coupling end CPL of the coupler 431 is coupled to the bonding pad PD48; and the isolating end CPisL of the coupler 431 is coupled to the load 432. The coupler 431 has a first coupling element and a second coupling element. The first coupling element is coupled between the input end CPin and the output end CPout, and the second coupling element is coupled between the coupling end CPL and the isolating end CPisL. For circuit details of the coupler 431, reference may be made to the embodiment in FIG. 1, and will not be described in detail here.

It should be noted that, on the third chip 430, the bonding wire W1 is disposed between the bonding pads PD46 and PD47, and the bonding wire W1 and the first coupling element in the coupler 431 are connected in parallel. Through the bonding wire W1, the possible insertion power loss generated by the amplifying circuit 411 can be reduced, and the performance of the system can be improved.

Incidentally, in other embodiments of the disclosure, one or more relay bonding pads may also be disposed on the third chip 430 so as to be sequentially connected between two of the bonding pad PD46, the relay bonding pad, and the bonding pad PD47 through splitting the bonding wire W1 into multiple sections of sub-bonding wires. For relevant implementation details, reference may be made to the embodiments in FIG. 2C and FIG. 2D, and will not be repeated here.

On the other hand, in the semi-conductor device 400, through disposing a bonding wire W41 between the bonding pad PD42 and the bonding pad PD43, the second end OUT1 of the first chip 410 and the first end E1 of the second chip 420 are electrically coupled to each other. Also, in the semi-conductor device 400, through disposing a bonding wire W42 between the bonding pad PD46 and the bonding pad PD45, the second end E2 of the second chip 420 and the input end CPin of the third chip 430 may also be electrically coupled to each other.

Please refer to FIG. 3 at the same time. The matching circuit is disposed between the power amplifier PA and the switching circuit 421. It is worth mentioning that, in this embodiment, the power amplifier and all of the matching circuit in the amplifying circuit 411 may all be disposed on the first chip 410. For example, the inductance L1 and the capacitance C2 are all disposed on the first chip 410. In other embodiments, merely the power amplifier and part of the matching circuit in the amplifying circuit 411 may be disposed on the first chip 410, and another part of the matching circuit may be disposed on the second chip 420. For example, part of the inductance L1 and the capacitance C2 is disposed on the first chip 410, and another part is disposed on the second chip 420. Alternatively, merely the amplifying circuit 411 may be disposed on the first chip 410, and all of the matching circuit may be disposed on the second chip 420. For example, the inductance L1 and the capacitance C2 are all disposed on the second chip 420.

In summary, in the front-end device of the disclosure, the switching circuit is disposed between the amplifying circuit and the coupler, and the bonding wire connected in parallel with the first coupling element is disposed on the first coupling element of the coupler. In this way, the insertion power loss of the amplifying circuit can be reduced, the power of a coupling signal output by the coupler can be correctly sensed, and the mismatch phenomenon between the amplifying circuit and the switching circuit can be reduced, and the overall performance of the system can be effectively improved.

What is claimed is:

1. A front-end circuit, comprising:
an amplifying circuit having a first end for receiving a radio-frequency signal to be amplified;
a switching circuit having a first end coupled to a second end of the amplifying circuit;
a coupler having a first coupling element and a second coupling element arranged adjacently, wherein a first end of the first coupling element is coupled to a second end of the switching circuit, and a second end of the first coupling element is coupled to a signal transmission end; and
at least one bonding wire having a first end coupled to the first end of the first coupling element, wherein a second end of the bonding wire is coupled to the second end of the first coupling element.

2. The front-end circuit as claimed in claim 1, wherein the bonding wire and the first coupling element are connected in parallel.

3. The front-end circuit as claimed in claim 1, wherein the first end of the first coupling element is coupled to a first bonding pad, the second end of the first coupling element is coupled to a second bonding pad, the first end of the bonding wire is coupled to the first bonding pad, and the second end of the bonding wire is coupled to the second bonding pad.

4. The front-end circuit as claimed in claim 3, wherein the bonding wire is a first bonding wire, and the front-end circuit further comprises a second bonding wire connected in parallel with the first bonding wire.

5. The front-end circuit as claimed in claim 3, wherein the bonding wire comprises a first sub-bonding wire and a second sub-bonding wire, a first end of the first sub-bonding wire is coupled to the first bonding pad, a second end of the first sub-bonding wire is coupled to a relay bonding pad, a first end of the second sub-bonding wire is coupled to the relay bonding pad, and a second end of the second sub-bonding wire is coupled to the second bonding pad.

6. The front-end circuit as claimed in claim 1, wherein the bonding wire further has a plurality of sub-bonding wires, and the plurality of sub-bonding wires are coupled between the first bonding pad and the second bonding pad by being disposed alternately and connected in series with a plurality of relay bonding pads.

7. The front-end circuit as claimed in claim 1, wherein a length of the first coupling element is substantially equal to a length of the bonding wire.

8. The front-end circuit as claimed in claim 1, wherein a signal coupling amount between the first coupling element and the bonding wire is less than a threshold value.

9. The front-end circuit as claimed in claim 1, wherein the switching circuit has a third end, and the third end of the switching circuit is coupled to a low noise amplifier.

10. The front-end circuit as claimed in claim 1, wherein a first end of the second coupling element is coupled to a coupling end of the coupler, and a second end of the second coupling element is coupled to a load.

11. The front-end circuit as claimed in claim 1, wherein the amplifying circuit comprises a power amplifier and an inductance, an input end of the power amplifier is for receiving the radio-frequency signal to be amplified, an output end of the power amplifier is for transmitting an amplified radio-frequency signal, a first end of the inductance is coupled to the output end of the power amplifier, and a second end of the inductance is coupled to the first end of the switching circuit.

12. The front-end circuit as claimed in claim 11, wherein the amplifying circuit further comprises at least one capacitance coupled to the inductance.

13. A semi-conductor device, comprising:
a first chip configured to dispose an amplifying circuit, wherein a first end of the amplifying circuit for receiving a radio-frequency signal to be amplified;
a second chip configured to dispose a switching circuit, wherein the switching circuit has a first end coupled to a second end of the amplifying circuit;
a third chip configured to dispose a coupler, wherein the coupler has a first coupling element and a second coupling element arranged adjacently, a first end of the first coupling element is coupled to a second end of the switching circuit, and a second end of the first coupling element is coupled to a signal transmission end; and
at least one bonding wire having a first end coupled to the first end of the first coupling element, wherein a second end of the bonding wire is coupled to the second end of the first coupling element.

14. The semi-conductor device as claimed in claim 13, wherein the bonding wire and the first coupling element are connected in parallel.

15. The semi-conductor device as claimed in claim 13, wherein the third chip has a first bonding pad and a second bonding pad, the first end of the first coupling element is coupled to the first bonding pad, the second end of the first coupling element is coupled to the second bonding pad, the first end of the bonding wire is coupled to the first bonding pad, and the second end of the bonding wire is coupled to the second bonding pad.

16. The semi-conductor device as claimed in claim 13, wherein the bonding wire is a first bonding wire, and the semi-conductor device further comprises a second bonding wire connected in parallel with the first bonding wire.

17. The semi-conductor device as claimed in claim 13, wherein the third chip further has a relay bonding pad, and the bonding wire comprises a first sub-bonding wire and a second sub-bonding wire, a first end of the first sub-bonding wire is coupled to the first bonding pad, a second end of the first sub-bonding wire is coupled to the relay bonding pad, a first end of the second sub-bonding wire is coupled the relay bonding pad, and a second end of the second sub-bonding wire is coupled to the second bonding pad.

18. The semi-conductor device as claimed in claim 13, wherein the bonding wire further has a plurality of sub-bonding wires, and the plurality of sub-bonding wires are coupled between the first bonding pad and the second bonding pad by being disposed alternately and connected in series with a plurality of relay bonding pads.

19. The semi-conductor device as claimed in claim 13, wherein a length of the first coupling element is substantially equal to a length of the bonding wire.

20. The semi-conductor device as claimed in claim 13, wherein the amplifying circuit comprises a power amplifier, an input end of the power amplifier is for receiving the radio-frequency signal to be amplified, an output end of the power amplifier is for transmitting an amplified radio-frequency signal, the semi-conductor device further comprises a matching circuit coupled between the power amplifier and the switching circuit, a part of the matching circuit is disposed on the first chip, and the other part of the matching circuit is disposed on the second chip.
